(19) United States
(12) Patent Application Publication
(10) Pub. No.: US 2024/0373677 A1
(43) Pub. Date: Nov. 7, 2024

(54) DISPLAY DEVICE

(71) Applicant: Samsung Display Co., LTD., Yongin-si (KR)

(72) Inventors: Jun Hee LEE, Yongin-si (KR); Yeong Ho LEE, Yongin-si (KR); Seong Yong HWANG, Yongin-si (KR); Choong Youl IM, Yongin-si (KR); Hyun Duck CHO, Yongin-si (KR); Beohm Rock CHOI, Yongin-si (KR)

(73) Assignee: Samsung Display Co., LTD., Yongin-si (KR)

(21) Appl. No.: 18/519,905

(22) Filed: Nov. 27, 2023

(30) Foreign Application Priority Data
May 3, 2023 (KR) 10-2023-0058009

(51) Int. Cl. H10K 59/122; H10K 59/126; H10K 59/38

(52) U.S. Cl. CPC H10K 59/122; H10K 59/126; H10K 59/38

(57) ABSTRACT

A display device may include: a substrate; a first electrode disposed on the substrate; a pixel defining layer including a pixel opening through which the first electrode is exposed; a second electrode disposed on the pixel defining layer and the first electrode; an encapsulation layer covering the second electrode; a color filter disposed on the encapsulation layer; and a light blocking component including a light opening overlapping the color filter. The pixel defining layer may include a first portion. At least a portion of the first portion may overlap an edge portion of the light blocking component. The first portion may be inclined.

### CROSS-REFERENCE TO RELATED APPLICATION(S)

This application claims priority to and benefits of Korean patent application number 10-2023-0058009 under 35 U.S.C. § 119, filed on May 3, 2023, the entire contents of which are incorporated herein by reference.

### BACKGROUND

### 1. Technical Field

Various embodiments relate to a display device, and more particularly, to a display device including a pixel defining layer.

### 2. Description of Related Art

Display devices display images, and may include a liquid crystal display (LCD), an organic light emitting diode (OLED) display, and the like. Such display devices are applied to various electronic devices such as cellular phones, navigation devices, digital cameras, electronic books, portable gaming consoles, and other types of terminals.

Display devices may include openings through which light emitted from light emitting elements is emitted outside the display devices. However, the openings may not only emit light generated from the light emitting elements but also transmit external light to be incident into the openings. Furthermore, the external light may be reflected by internal components of the display devices and emitted through the openings. Thus, color representation of the display devices may be distorted due to reflective light generated by the reflection of the external light.

### SUMMARY

Various embodiments are directed to a display device including a pixel defining layer having a tapered portion.

However, embodiments of the disclosure are not limited to those set forth herein. The above and other embodiments will become more apparent to one of ordinary skill in the art to which the disclosure pertains by referencing the detailed description of the disclosure given below.

In an embodiment, a display device may include: a substrate; a first electrode disposed on the substrate; a pixel defining layer including a pixel opening through which the first electrode is exposed; a second electrode disposed on the pixel defining layer and the first electrode; an encapsulation layer covering the second electrode; a color filter disposed on the encapsulation layer; and a light blocking component including a light opening overlapping the color filter. The pixel defining layer may include a first portion. At least a portion of the first portion may overlap an edge portion of the light blocking component. The first portion may be inclined.

In an embodiment, a height of the first portion may decrease as being farther from the pixel opening.

In an embodiment, an inclination of the first portion may be in a range of about 10° to about 45°.

In an embodiment, a first portion with a lowest height in the first portion may overlap the light blocking component.

In an embodiment, a first portion with a lowest height in the first portion may be spaced apart from the edge portion of the light blocking component by a horizontal distance of about 1 μm or more.

In an embodiment, a difference in height between a first portion with a lowest height and a second portion with a highest height in the first portion may be in a range of about 0.3 μm to about 1 μm.

In an embodiment, the pixel defining layer may further include a second portion adjacent to the first portion as being farther from the pixel opening. The second portion may be inclined.

In an embodiment, a height in the second portion may increase as being farther from the pixel opening.

In an embodiment, the pixel defining layer may further include a third portion adjacent to the second portion as being farther from the pixel opening. The third portion may have a certain height.

In an embodiment, the height of the third portion may be in a range of about 1.5 μm to about 1.7 μm.

In an embodiment, the pixel defining layer may further include a second portion adjacent to the first portion as being farther from the pixel opening. The second portion may have a certain height.

In an embodiment, the pixel defining layer may further include a fourth portion adjacent to the first portion in a direction toward the pixel opening. The fourth portion may be inclined.

In an embodiment, an inclination of the fourth portion may be in a range of about 15° to about 35°.

In an embodiment, the pixel opening may have a surface area less than a surface area of the light opening.

In an embodiment, the pixel opening may include a first pixel opening defining a first emission area formed to display a first color, a second pixel opening defining a second emission area formed to display a second color, and a third pixel opening defining a third emission area formed to display a third color. The first portion may be included in a portion of the pixel defining layer that defines the first pixel opening.

In an embodiment, the pixel opening may include a first pixel opening defining a first emission area formed to display a first color, a second pixel opening defining a second emission area formed to display a second color, a first sub-pixel opening defining a first sub-emission area formed to display a third color, and a second sub-pixel opening defining a second sub-emission area formed to display the third color. The first portion may be included in a portion of the pixel defining layer that defines the first sub-pixel opening.

In an embodiment, a display device may include: a substrate; a first electrode disposed on the substrate; a pixel defining layer including a pixel opening through which the first electrode is exposed; a second electrode disposed on the pixel defining layer and the first electrode; an encapsulation layer covering the second electrode; a first color filter disposed on the encapsulation layer; and a second color filter disposed at least partially over the first color filter. The pixel defining layer may include a first portion. At least a portion of the first portion may overlap an edge portion of an overlapping area where the first color filter and the second color filter overlap each other. The first portion may be inclined.

In an embodiment, a height of the first portion may decrease as being farther from the pixel opening.

In an embodiment, a first portion with a lowest height in the first portion may overlap the overlapping area.

In an embodiment, a first portion with a lowest height in the first portion may be spaced apart from the edge portion of the overlapping area by a horizontal distance of about 1 μm or more.

### BRIEF DESCRIPTION OF THE DRAWINGS

FIG. 1 is a schematic perspective view illustrating an electronic device in accordance with an embodiment.

FIG. 2 is a schematic perspective view of a display device included in the electronic device in accordance with an embodiment.

FIG. 3 is a schematic sectional view of the display device of FIG. 2.

FIG. 4 is a schematic plan view illustrating a connection relationship between components of the display device in accordance with an embodiment.

FIG. 5 is a schematic plan view illustrating arrangement of an emission area, a color filter, and a light blocking component in a display area of the display device in accordance with an embodiment.

FIG. 6 is a schematic sectional view taken along line VI-VI′ of FIG. 5.

FIG. 7 is a schematic diagram illustrating a pixel defining layer and a light blocking component of the display device in accordance with embodiments.

FIG. 8A is a schematic diagram illustrating a comparative example in which external light is incident on the pixel defining layer.

FIG. 8B is a schematic diagram illustrating an example where external light is incident on the pixel defining layer of the display device of FIG. 7.

FIG. 9 provides schematic diagrams illustrating the quantity of total reflected light (e.g., specular component included; SCI) from the display device.

FIG. 10 is a schematic diagram illustrating a pixel defining layer and a light blocking component of the display device in accordance with embodiments.

FIG. 11 is a schematic sectional view of the display device taken along line VI-VI′ of FIG. 5, in accordance with embodiments.

FIG. 12 is a schematic diagram illustrating the pixel defining layer and the color filter of the display device of FIG. 11.

FIG. 13 is a schematic diagram illustrating an example where external light is incident on the pixel defining layer of the display device of FIG. 11.

FIG. 14 is a schematic diagram illustrating the pixel defining layer and the color filter of the display device in accordance with embodiments.

### DETAILED DESCRIPTION OF THE EMBODIMENTS

In the following description, for the purposes of explanation, numerous specific details are set forth in order to provide a thorough understanding of various embodiments or implementations of the invention. As used herein “embodiments” and “implementations” are interchangeable words that are non-limiting examples of devices or methods disclosed herein. It is apparent, however, that various embodiments may be practiced without these specific details or with one or more equivalent arrangements. Here, various embodiments do not have to be exclusive nor limit the disclosure. For example, specific shapes, configurations, and characteristics of an embodiment may be used or implemented in another embodiment.

Unless otherwise specified, the illustrated embodiments are to be understood as providing features of the invention. Therefore, unless otherwise specified, the features, components, modules, layers, films, panels, regions, and/or aspects, etc. (hereinafter individually or collectively referred to as “elements”), of the various embodiments may be otherwise combined, separated, interchanged, and/or rearranged without departing from the invention.

The use of cross-hatching and/or shading in the accompanying drawings is generally provided to clarify boundaries between adjacent elements. As such, neither the presence nor the absence of cross-hatching or shading conveys or indicates any preference or requirement for particular materials, material properties, dimensions, proportions, commonalities between illustrated elements, and/or any other characteristic, attribute, property, etc., of the elements, unless specified. Further, in the accompanying drawings, the size and relative sizes of elements may be exaggerated for clarity and/or descriptive purposes. When an embodiment may be implemented differently, a specific process order may be performed differently from the described order. For example, two consecutively described processes may be performed substantially at the same time or performed in an order opposite to the described order. Also, like reference numerals denote like elements.

When an element, such as a layer, is referred to as being “on,” “connected to,” or “coupled to” another element or layer, it may be directly on, connected to, or coupled to the other element or layer or intervening elements or layers may be present. When, however, an element or layer is referred to as being “directly on,” “directly connected to,” or “directly coupled to” another element or layer, there are no intervening elements or layers present. To this end, the term “connected” may refer to physical, electrical, and/or fluid connection, with or without intervening elements. Further, the DR1-axis, the DR2-axis, and the DR3-axis are not limited to three axes of a rectangular coordinate system, such as the X, Y, and Z-axes, and may be interpreted in a broader sense. For example, the DR1-axis, the DR2-axis, and the DR3-axis may be perpendicular to one another, or may represent different directions that are not perpendicular to one another. Further, the X-axis, the Y-axis, and the Z-axis are not limited to three axes of a rectangular coordinate system, such as the x, y, and z axes, and may be interpreted in a broader sense. For example, the X-axis, the Y-axis, and the Z-axis may be perpendicular to one another, or may represent different directions that are not perpendicular to one another. For the purposes of this disclosure, “at least one of A and B” may be construed as understood to mean A only, B only, or any combination of A and B. Also, “at least one of X, Y, and Z” and “at least one selected from the group consisting of X, Y, and Z” may be construed as X only, Y only, Z only, or any combination of two or more of X, Y, and Z. As used herein, the term “and/or” includes any and all combinations of one or more of the associated listed items.

Although the terms “first,” “second,” etc. may be used herein to describe various types of elements, these elements should not be limited by these terms. These terms are used to distinguish one element from another element. Thus, a first element discussed below could be termed a second element without departing from the teachings of the disclosure.

Spatially relative terms, such as “beneath,” “below,” “under,” “lower,” “above,” “upper,” “over,” “higher,” “side” (e.g., as in “sidewall”), and the like, may be used herein for descriptive purposes, and, thereby, to describe one elements relationship to another element(s) as illustrated in the drawings. Spatially relative terms are intended to encompass different orientations of an apparatus in use, operation, and/or manufacture in addition to the orientation depicted in the drawings. For example, if the apparatus in the drawings is turned over, elements described as “below” or “beneath” other elements or features would then be oriented “above” the other elements or features. Thus, the term “below” can encompass both an orientation of above and below. Furthermore, the apparatus may be otherwise oriented (e.g., rotated 90 degrees or at other orientations), and, as such, the spatially relative descriptors used herein interpreted accordingly.

The terminology used herein is for the purpose of describing particular embodiments and is not intended to be limiting. As used herein, the singular forms, “a,” “an,” and “the” are intended to include the plural forms as well, unless the context clearly indicates otherwise. Moreover, the terms “comprises,” “comprising,” “includes,” and/or “including,” when used in this specification, specify the presence of stated features, integers, steps, operations, elements, components, and/or groups thereof, but do not preclude the presence or addition of one or more other features, integers, steps, operations, elements, components, and/or groups thereof. It is also noted that, as used herein, the terms “substantially,” “about,” and other similar terms, are used as terms of approximation and not as terms of degree, and, as such, are utilized to account for inherent deviations in measured, calculated, and/or provided values that would be recognized by one of ordinary skill in the art.

Various embodiments are described herein with reference to sectional and/or exploded illustrations that are schematic illustrations of embodiments and/or intermediate structures. As such, variations from the shapes of the illustrations as a result, for example, of manufacturing techniques and/or tolerances, are to be expected. Thus, embodiments disclosed herein should not necessarily be construed as limited to the particular illustrated shapes of regions, but are to include deviations in shapes that result from, for instance, manufacturing. In this manner, regions illustrated in the drawings may be schematic in nature and the shapes of these regions may not reflect actual shapes of regions of a device and, as such, are not necessarily intended to be limiting.

As customary in the field, some embodiments are described and illustrated in the accompanying drawings in terms of functional blocks, units, and/or modules. Those skilled in the art will appreciate that these blocks, units, and/or modules are physically implemented by electronic (or optical) circuits, such as logic circuits, discrete components, microprocessors, hard-wired circuits, memory elements, wiring connections, and the like, which may be formed using semiconductor-based fabrication techniques or other manufacturing technologies. In the case of the blocks, units, and/or modules being implemented by microprocessors or other similar hardware, they may be programmed and controlled using software (e.g., microcode) to perform various functions discussed herein and may optionally be driven by firmware and/or software. It is also contemplated that each block, unit, and/or module may be implemented by dedicated hardware, or as a combination of dedicated hardware to perform some functions and a processor (e.g., one or more programmed microprocessors and associated circuitry) to perform other functions. Also, each block, unit, and/or module of some embodiments may be physically separated into two or more interacting and discrete blocks, units, and/or modules without departing from the scope of the invention. Further, the blocks, units, and/or modules of some embodiments may be physically combined into more complex blocks, units, and/or modules without departing from the scope of the invention.

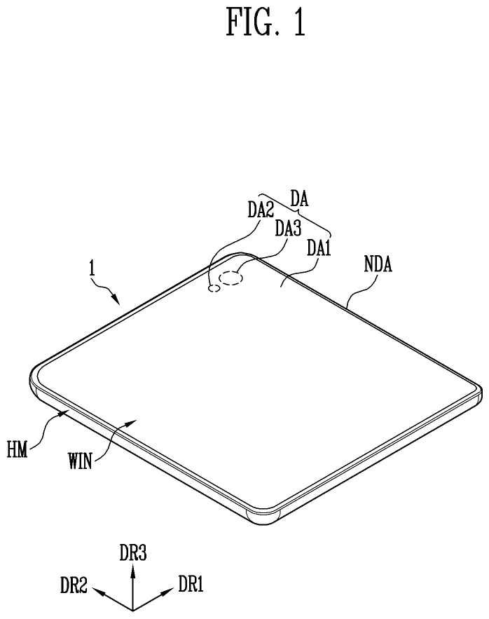

FIG. 1 is a schematic perspective view illustrating an electronic device 1 in accordance with an embodiment.

Referring to FIG. 1, the electronic device 1 may include a display screen capable of displaying a video or a static image in a third direction DR3. For example, the electronic device 1 may include a television, a laptop computer, a monitor, an advertising board, Internet of Things (IoT), a mobile phone, a smartphone, a tablet personal computer (PC), an electronic watch, a smartwatch, a watch phone, a head-mounted display, a mobile communication terminal, an electronic notepad, an e-book, a portable multimedia player (PMP), a navigation device, a gaming console, a digital camera, a camcorder, and the like that include a display screen.

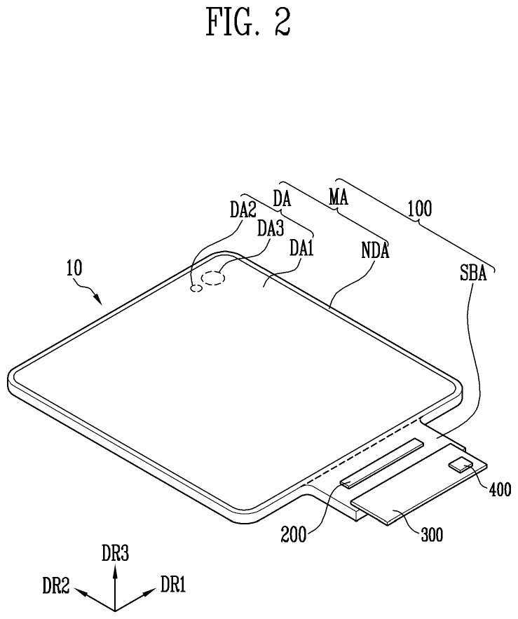

The electronic device 1 may include a cover window WIN and a housing HM. A display device 10 illustrated in FIG. 2 may be positioned inside the cover window WIN and the housing HM. Hence, the cover window WIN and the housing HM may be combined to each other to form an external appearance of the electronic device 1.

The cover window WIN may include an insulating panel. For example, the cover window WIN may be formed of glass, plastic, or a combination thereof. In an embodiment, the cover window WIN may include a touch sensing component that detects a touch.

A front surface of the cover window WIN may define a front surface of the electronic device 1.

The housing HM may be combined with the cover window WIN. The cover window WIN may be disposed on a front surface of the housing HM. The housing HM may be combined with the cover window WIN to provide a certain reception space. The display device 10 may receive the certain reception space provided between the housing HM and the cover window WIN.

The housing HM may include a material having relatively high rigidity. For example, the housing HM may include a plurality of frames and/or plates including glass, plastic, metal, or formed of a combination of glass, plastic, and metal. The housing HM may have a rear surface and sidewalls, and the cover window WIN may be disposed on an upper portion of the housing HM, so that components of the display device 10 that are received in internal space defined by the housing HM and the cover window WIN may be reliably protected from external impacts.

The electronic device 1 may include a display device (refer to reference numeral 10 in FIG. 2) that includes a display screen in the third direction DR3. The display device included in the electronic device 1 may employ various display devices such as an inorganic light emitting display device, an organic light emitting display device, a quantum dot display device, and the like. The following description focuses on the case where a light emitting display device including an organic light emitting element is applied as an example of the display device, but embodiments are not limited thereto, and the following description may be applied to other display devices, so long as the same technical notion may be applied thereto.

The shape of the electronic device 1 may be changed in various ways. For example, the electronic device 1 may have various shapes such as a long horizontal rectangle, a long vertical rectangle, a square, a square with rounded corners, other polygonal shapes, or a circular shape. The shape of a display area DA of the electronic device 1 may be similar to the overall shape of the electronic device 1. Although FIG. 1 illustrates an electronic device 1 with a relatively long rectangular shape in a first direction DR1, embodiments are not limited thereto.

The electronic device 1 may include the display area DA and a non-display area NDA. The display area DA and the non-display area NDA illustrated in FIG. 1 may correspond to (or overlap) a display area DA and a non-display area NDA of the display device 10. The display area DA may be an area which displays an image, and the non-display area NDA may be an area which does not display an image. The display area DA may occupy a significant portion of the electronic device 1, and may be centered around the center portion of the electronic device 1. The non-display area NDA may have a structure surrounding (or enclosing) the periphery of the display area DA.

The display area DA may include a first display area DA1, a second display area DA2, and a third display area DA3. The second display area DA2 and the third display area DA3 may be areas where components such as a sensor and a camera for providing various functions to the electronic device 1 are disposed on a rear surface (e.g., a bottom surface in the third direction DR3) of the electronic device 1. The second display area DA2 and the third display area DA3 may correspond to (or overlap) component areas. The second display area DA2 and the third display area DA3 may be surrounded (or enclosed by the first display area DA1. Both the first display area DA1 and the second display area DA2 and the third display area DA3 may display images. The positions and numbers of the second display area DA2 and the third display area DA3 may be changed in various ways according to the embodiment.

Hereinafter, the structure of a display device in accordance with an embodiment will be described with reference to FIG. 2.

FIG. 2 is a schematic perspective view of a display device 10 included in the electronic device 1 in accordance with an embodiment.

Referring to FIG. 2, the electronic device 1 in accordance with an embodiment may include the display device 10. The display device 10 may display an image on the electronic device 1, and may function to detect or capture a front side of the electronic device 1. The display device 10 may have a planar shape similar to that of the electronic device 1. For example, the display device 10 may have a shape similar to a rectangle with sides in a first direction DR1 and sides in a second direction DR2. Corner portions where the sides in the first direction DR 1 and the second direction DR2 meet may be rounded to have a curvature, but embodiments are not limited thereto. For example, corner portions may be formed with right angles. The planar shape of the display device 10 is not limited to a rectangular shape, and may have shapes similar to other polygonal shapes, a circular shape, or an elliptical shape.

The display device 10 may have a display panel 100, a display driver 200, a circuit board 300, and a touch driver 400.

The display panel 100 may include a main area MA and a sub-area SBA.

The main area MA may include a display area DA including pixels provided to display an image, and a non-display area NDA disposed around the display area DA. The display area DA may include a first display area DA1, a second display area DA2, and a third display area DA3. The second display area DA2 and the third display area DA3 may not only include pixels but also include components such as a sensor and a camera disposed in lower portions thereof in the third direction DR3. The second display area DA2 and the third display area DA3 may correspond to (or overlap) component areas.

The display area DA may emit light from emission areas corresponding to light emitting elements in the third direction DR3. For example, the display panel 100 may include a light emitting element, and a pixel circuitry including a transistor, and may include a pixel defining layer having an opening which defines an emission area of the light emitting element. For example, the light emitting element may include at least one of an organic light emitting diode (OLED) including an organic emission layer, a quantum dot LED (QLED) including a quantum dot emission layer, an inorganic LED including an inorganic semiconductor, or a micro LED, but embodiments are not limited thereto.

The non-display area NDA may be an area formed outside the display area DA, and may surround (or enclose) the display area DA. The non-display area NDA may be defined as an edge area of the main area MA of the display panel 100. The non-display area NDA may include a gate driver configured to supply gate signals to gate lines, and fan-out lines that connect the display driver 200 to the display area DA.

The sub-area SBA may be an area extending from a side of the main area MA. The sub-area SBA may include flexible materials that are capable of bending, folding, rolling, and/or rolling, or that have similar properties. For example, in the case where the sub-area SBA is bent, the sub-area SBA may overlap the main area MA in the thickness direction (e.g., in the third direction DR3). The sub-area SBA may include the display driver 200, and a pad component connected to the circuit board 300. In an embodiment, the sub-area SBA may be omitted, and the display driver 200 and the pad component may be disposed in the non-display area NDA.

The display driver 200 may output signals and voltages for driving the display panel 100. The display driver 200 may supply data voltages to data lines. The display driver 200 may supply a power voltage to a power line, and may supply a gate control signal to the gate driver. The display driver 200 may be formed on an integrated circuit (IC), and may be mounted on the display panel 100 in a chip on glass (COG) scheme, a chip on plastic (COP) scheme, or an ultrasonic bonding scheme. For example, the display driver 200 may be disposed in the sub-area, and may overlap the main area MA in the thickness direction (e.g., in the third direction DR3) by bending the sub-area SBA. In another example, the display driver 200 may be mounted on the circuit board 300.

The circuit board 300 may be attached to the pad component of the display panel 100 by using an anisotropic conductive film (ACF). Lead lines of the circuit board 300 may be electrically connected to the pad component of the display panel 100. The circuit board 300 may be formed as a flexible printed circuit board, a printed circuit board, or a flexible film such as a chip on film.

The touch driver 400 may be mounted on the circuit board 300. The touch driver 400 may be electrically connected to the touch sensing component included in the electronic device 1. The touch driver 400 may supply touch driving signals to sensing electrodes of the touch sensing component, and may sense changes in capacitance between the sensing electrodes. For example, the touch driving signal may be a pulse signal having a certain frequency. The touch driver 400 may determine whether touch input is present and coordinates of the touch input, based on the changes in capacitance between the sensing electrodes. The touch driver 400 may be formed of an integrated circuit IC.

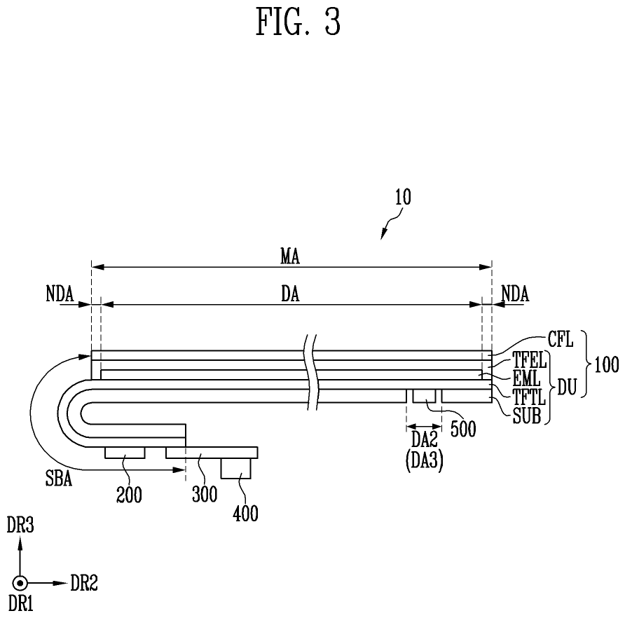

Hereinafter, the sectional structure of the display device 10 will be described with reference with FIG. 3.

FIG. 3 is a schematic sectional view of the display device of FIG. 2.

Referring to FIG. 3, the display panel 100 may include a display layer DU, and an external light attenuation layer CFL. The display layer DU may include a substrate SUB, a driving element layer TFTL, a light-emitting-element layer EML, and an encapsulation layer TFEL.

The substrate SUB may be a base substrate or a base component. The substrate SUB may be a flexible substrate which is bendable, foldable, rollable, or the like. For example, the substrate SUB may include polymer resin such as polyimide (PI), but embodiments are not limited thereto. In an embodiment, the substrate SUB may include glass or metal.

The driving element layer TFTL may be disposed on the substrate SUB. The driving element layer TFTL may include transistors and capacitors that form the pixel circuitry configured to output and transmit current to the light emitting elements. The driving element layer TFTL may further include gate lines, data lines, power lines, gate control lines, fan-out lines that connect the display driver 200 to the data lines, and lead lines that connect the display driver 200 to the pad component. Each of the transistors may include a semiconductor including a channel area, a source area, and a drain area, and a gate electrode positioned on a side of the semiconductor. For example, the source area and the drain area of the semiconductor may respectively function as a source electrode (e.g., a first electrode) and a drain electrode (e.g., a second electrode) of the transistor. Furthermore, in the case where the gate driver is formed on a side of the non-display area NDA of the display panel 100, the gate driver may include transistors.

The driving element layer TFTL may be disposed in the display area DA, the non-display area NDA, and the sub-area SBA. The transistors, the gate lines, the data lines, and the power lines of the driving element layer TFTL may be disposed in the display area DA. The gate control lines and the fan-out lines of the driving element layer TFTL may be disposed in the non-display area NDA. The lead lines of the driving element layer TFTL may be disposed in the sub-area SBA.

The light-emitting-element layer EML may be provided with light emitting elements and a corresponding emission area, and may disposed on the driving element layer TFTL. The light-emitting-element layer EML may include light emitting elements each including a first electrode, a second electrode, and an emission layer to emit light, and a pixel defining layer having an opening (hereinafter referred also to as a pixel opening) that defines the emission area. The light emitting elements of the light-emitting-element layer EML may be disposed in the display area DA.

In an embodiment, the light-emitting-element layer may be formed of an organic light emitting layer including an organic material. A functional layer including at least one layer among an electron injection layer, an electron transport layer, a hole transport layer, and a hole injection layer may be positioned on opposite sides of the emission layer. For example, the combination of the emission layer and the functional layer may be referred to as an intermediate layer. In case that the first electrode receives a voltage through a transistor of the driving element layer TFTL and the second electrode receives a low driving voltage, holes and electrons may move to the organic emission layer respectively through the hole injection layer and the hole transport layer and through the electron injection layer and the electron transport layer, and combine with each other, thereby emitting light. For example, one of the first electrode and the second electrode may be an anode, and the other one may be a cathode.

In an embodiment, the light emitting element may be a quantum dot light emitting element with a quantum dot emission layer, an inorganic light emitting element with an inorganic semiconductor, or a micro light emitting element.

The encapsulation layer TFEL may cover a top surface and side surfaces of the light-emitting-element layer EML, and may protect the light-emitting-element layer EML to prevent external water or air from penetrating into the light-emitting-element layer EML. The encapsulation layer TFEL may include at least one inorganic layer and at least one organic layer to encapsulate the light-emitting-element layer EML.

The external light attenuation layer CFL may be disposed on the encapsulation layer TFEL. The external light attenuation layer CFL may include color filters that respectively correspond to (or overlap) emission areas. Furthermore, a light blocking component may be positioned between adjacent color filters or in an overlapping portion of the adjacent color filters in the external light attenuation layer CFL. The light blocking component may be positioned on an upper side or a lower side of the color filter in the third direction DR3, or may be positioned on sides (e.g., opposite sides) thereof.

As the external light attenuation layer CFL is directly disposed on the encapsulation layer TFEL, the display device 10 may not require a separate substrate for the external light attenuation layer CFL. Furthermore, a polarizing plate may not be attached to a top surface of the external light attenuation layer CFL. As a result, the thickness of the display device 10 may be relatively small. For example, the absence of the polarizing plate in the display device 10 may lead to a problem of direct reflection of external light, but the color filters or light blocking component in the external light attenuation layer CFL may provide the advantage of reducing the reflection of external light. For example, the color filters may selectively transmit light of specific wavelengths, and may block or absorb light of other wavelengths. The light blocking component may absorb external light. Hence, the quantity of external light entering the display device 10 may be reduced, and the quantity of reflected light may also be reduced. As a result, the problem associated with the reflection of external light may be mitigated.

In an embodiment, the display device 10 may further include an optical device 500. The optical device 500 may be disposed on a rear surface of the second display area DA2 or the third display area DA3. The optical device 500 may emit or receive light in the infrared, ultraviolet, visible ray bands. For example, the optical device 500 may be an optical sensor, such as a proximity sensor, an ambient light sensor, a camera sensor, or an image sensor, which detects light that is incident on the display device 10.

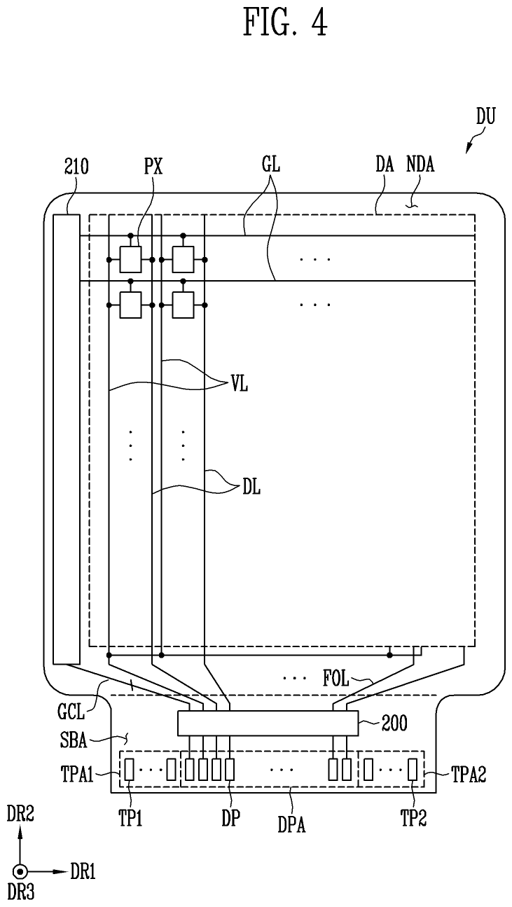

Hereinafter, the connection relationship of the components included in the display device 10 will be described in detail with reference to FIG. 4.

FIG. 4 is a schematic plan view illustrating a connection relationship between the components of the display device 10 in accordance with an embodiment.

Referring to FIG. 4, the display layer DU of the display device 10 may include a display area DA and a non-display area NDA.

The display area DA may be disposed in a central portion of the display panel 100. Unit pixels PX, gate lines GL, data lines DL, and power lines VL may be disposed in the display area DA. Each of the unit pixels PX represents the minimum unit that emits light, and includes a pixel circuitry that includes a transistor and a capacitor, and a light emitting element that receives current from the pixel circuitry.

Each unit pixel PX may be connected to the corresponding gate line GL, the corresponding data line DL, and the corresponding power line VL. Each of the gate line GL and the power line VL may include a plurality of lines.

The gate lines GL may supply gate signals received from the gate driver 210 to unit pixels PX. The gate lines GL may extend in the first direction DR1, and may be spaced apart from each other in the second direction DR2, which intersects the first direction DR1.

The data lines DL may supply data voltages received from the display driver 200 to unit pixels PX. The data lines DL may extend in the second direction DR2, and may be spaced apart from each other in the first direction DR1.

The power lines VL may supply power voltages received from the display driver 200 to the unit pixels PX. For example, the power voltages may include at least one of a driving voltage, an initialization voltage, a reference voltage, and a low driving voltage. The power voltages may be transmitted to the unit pixels PX. The power lines VL may extend in the second direction DR2, and may be spaced apart from each other in the first direction DR1.

The non-display area NDA may surround (or enclose) the display area DA. The gate driver 210, fan-out lines FOL, and gate control lines GCL may be disposed in the non-display area NDA.

The gate driver 210 may generate gate signals based on a gate control signal, and may sequentially supply gate signals to the gate lines GL in a preset order.

The fan-out lines FOL may extend from the display driver 200 to the display area DA. The fan-out lines FOL may supply data voltages received from the display driver 200 to the data lines DL.

The gate control line GCL may extend from the display driver 200 to the gate driver 210. The gate control line GCL may supply gate control signals received from the display driver 200 to the gate driver 210.

Referring to FIG. 4, the display device 10 may further include a sub-area SBA.

The sub-area SBA may include the display driver 200, a pad area PA, and first and second touch pad areas TPA1 and TPA2.

The display driver 200 may output signals and voltages for driving the display panel 100 to the fan-out lines FOL. The display driver 200 may supply data voltages to the data lines DL through the fan-out lines FOL. The data voltages may be supplied to unit pixels PX, thus controlling the luminances of the unit pixels PX. The display driver 200 may supply gate control signals to the gate driver 210 through the gate control lines GCL.

The pad area PA, the first touch pad area TPA1, and the second touch pad area TPA2 may be disposed in the perimeter of the sub-area SBA. The pad area PA may include display pad components DP. The display pad component DP may be connected to a graphic system through the circuit board 300. The display pad components DP may be connected to the circuit board 300, and may receive digital video data and supply the digital video data to the display driver 200. The first touch pad area TPA1 and the second touch pad area TPA2 may respectively include touch pads TP1 and TP2, and may be connected to the touch driver 400 positioned in the circuit board 300 to enable touch detection. The pad area PA, the first touch pad area TPA1, and the second touch pad area TPA2 may be electrically connected to the circuit board 300 by using materials such as anisotropic conductive film or self assembly anisotropic conductive paste (SAP).

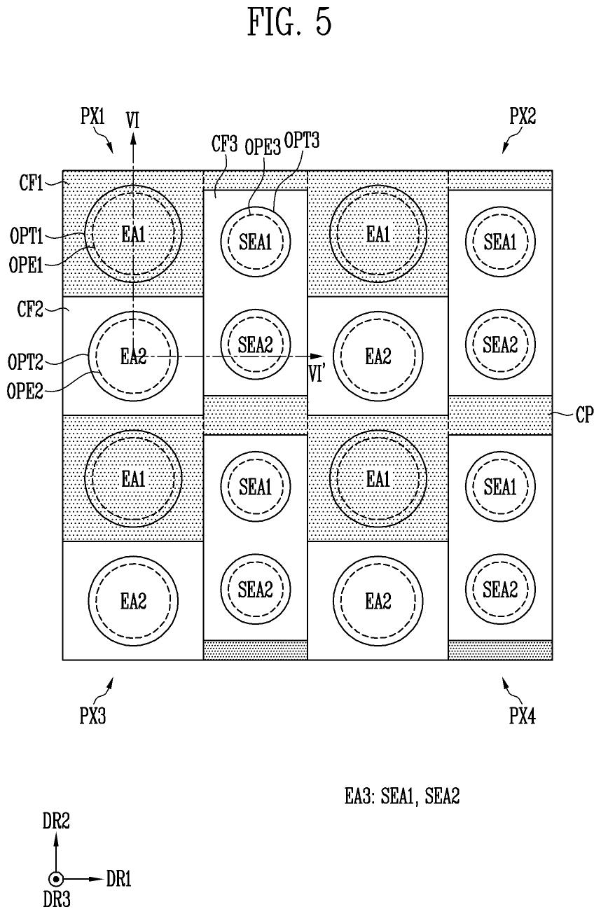

Hereinafter, a position relationship between the pixel opening of the pixel defining layer positioned in the light-emitting-element layer EML and the color filter and the light blocking component positioned in the external light attenuation layer CFL will be described with reference to a plan view of FIG. 5.

FIG. 5 is a schematic plan view illustrating arrangement of the emission area, the color filter, and the light blocking component in the display area DA of the display device in accordance with an embodiment.

In FIG. 5, pixel openings OPE1, OPE2, and OPE3 of the pixel defining layer and light openings OPT1, OPT2, and OPT3 of the light blocking component (hereinafter, referred also to as light openings) are depicted as a circular shape. Color filters CF1, CF2, and CF3 are depicted as straight lines, indicating separation therebetween.

The pixel openings OPE1, OPE2, and OPE3 and the light openings OPT1, OPT2, and OPT3 may have a circular form in a plan view. The circular shape may function for the reflection of light without specific directionality, thus resulting in the advantageous reduction of the reflective characteristics. In case that the planar shape of the opening has corner portions, it is disadvantageous in that light reflected in the corresponding direction is easily visible to the user. Further, a circular opening, which does not have corner portions, may have the advantage of having the lowest reflective characteristics.

Referring to FIG. 5, the display device 10 may include unit pixels PX1, PX2, PX3, and PX4 disposed in the display area DA, and emission areas EA1, EA2, and EA3 disposed in each of the unit pixels PX1, PX2, PX3, and PX4. The display area DA depicted in FIG. 5 corresponds to the first display area DA1. The unit pixels PX1, PX2, PX3, and PX4 and the emission areas EA1, EA2, and EA3 may be disposed in the first display area DA1. Unit pixels PX1, PX2, PX3, and PX4 and emission areas EA1, EA2, and EA3 may also be disposed in the second display area DA2 and the third display area DA3 within the display area DA.

The unit pixels PX1, PX2, PX3, and PX4 may include emission areas EA1, EA2, and EA3 formed to display different colors of light, and may be arranged in the first direction DR1 and the second direction DR2. The first unit pixel PX1 and the second unit pixel PX2 may be adjacent to each other in the first direction DR1. The first unit pixel PX1 and the third unit pixel PX3 may be adjacent to each other in the second direction DR2. The third unit pixel PX3 and the fourth unit pixel PX4 may be adjacent to each other in the first direction DR1. The second unit pixel PX1 and the fourth unit pixel PX4 may be adjacent to each other in the second direction DR2. However, the arrangement or array of the unit pixels PX1, PX2, PX3, and PX4 is not limited to that depicted in FIG. 5. In an embodiment, the unit pixels PX1, PX2, PX3, and PX4 may be arranged in a PENTILE™ type such as a diamond PENTILE™ type.

The emission areas EA1, EA2, and EA3 of each of the unit pixels PX1, PX2, PX3, and PX4 may include a first emission area EA1, a second emission area EA2, and a third emission area EA3, which emit different colors of light. Unlike the first emission area EA1 or the second emission area EA2, the third emission area EA3 may include sub-emission areas SEA1 and SEA2 spaced apart from each other. The third emission area EA3 may include a first sub-emission area SEA1 and a second sub-emission area SEA2 spaced apart from the first sub-emission area SEA1 in the second direction DR2. The first sub-emission area SEA1 and the second sub-emission area SEA2 may be structurally separated from each other, but may emit the same color of light and thus form a single third emission area EA3.

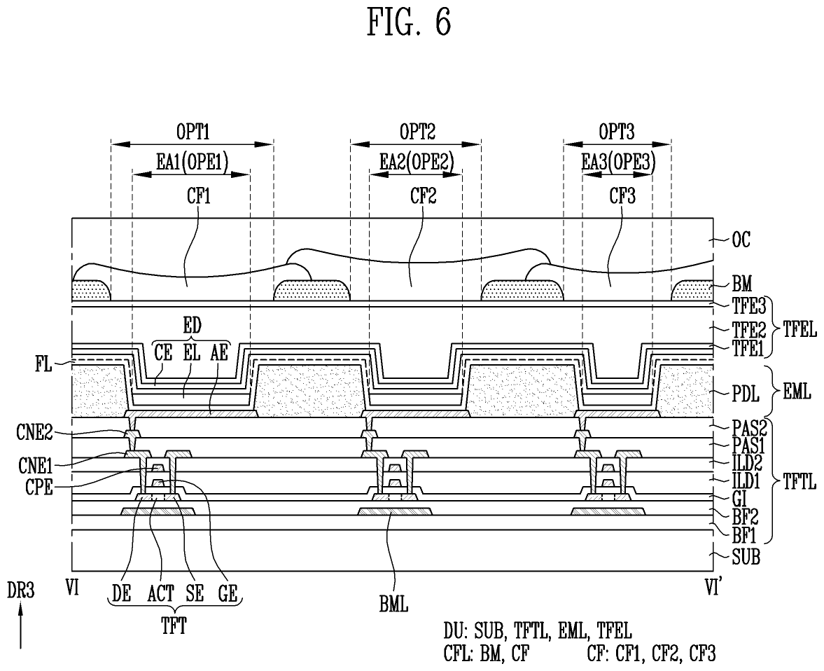

The first to third emission areas EA1, EA2, and EA3 may respectively emit red light, green light, and blue light. The color of light emitted from each of the emission areas EA1, EA2, and EA3 may vary according to an emission layer (refer to ‘EL’ of FIG. 6) of a light emitting element (refer to ‘ED’ of FIG. 6) disposed in the light-emitting-element layer EML, which will be described below. In an embodiment, the first emission area EA1 may emit first light of red. The second emission area EA2 may emit second light of green. The third emission area EA3 or the sub-emission areas SEA1 and SEA3 of the third emission area EA3 may emit third light of blue.

Each of the emission areas EA1, EA2, and EA3 may have a circular shape in a plan view. For example, a planar structure without corners may have the advantage of reducing the reflective characteristics. In an embodiment, the emission areas EA1, EA2, and EA3 may have elliptical shapes, circular shapes, or similar shapes.

In the unit pixels PX1, PX2, PX3, and PX4, the emission areas EA1, EA2, and EA3 may be arranged in the first direction DR1, the second direction DR2, or a diagonal direction therebetween. For example, the first emission area EA1 and the second emission area EA2 may be disposed at positions spaced apart from each other in the second direction DR2 in each of the unit pixels PX1, PX2, PX3, and PX4. In an embodiment, in the overall surface of the display area DA, the first emission areas EA1 and the second emission areas EA2 may be alternately disposed in the second direction DR2. The first emission area EA1 of the third unit pixel PX3 may be disposed between the second emission area EA2 of the first unit pixel PX1 and the second emission area EA2 of the third unit pixel PX3.

The third emission area EA3 may be disposed in each of the unit pixels PX1, PX2, PX3, and PX4 at a position spaced apart from the first emission area EA1 and the second emission area EA2 in the first direction DR1. The third emission area EA3 may have a length in the second direction DR2, which is less than the sum of the lengths of the first emission area EA1 and the second emission area EA2 in the second direction DR2. In an embodiment of FIG. 5, the third emission areas EA3 may be positioned on opposite sides based on the center portion of the length of each of the first emission area EA1 and the second emission area EA2 in the second direction DR2. Color pattern layers CP may be positioned on opposite sides of the third emission area EA3. For example, the color pattern layer CP may protrude from the first color filter CF1 in the first direction DR1. The color pattern layer CP and the first color filter CF1 may include the same materials. The color pattern layer CP may be a portion, which is integral with the first color filter CF1.

The third emission area EA3 may include sub-emission areas SEA1 and SEA2. The first sub-emission area SEA1 may be disposed in each of the unit pixels PX1, PX2, PX3, and PX4 at a position spaced apart from the first emission area EA1 in the first direction DR1. The second sub-emission area SEA2 may be disposed in each of the unit pixels PX1, PX2, PX3, and PX4 at a position spaced apart from the second emission area EA2 in the first direction DR1.

The third emission areas EA3, or the sub-emission areas SEA1 and SEA2 of the third emission areas EA3 may be repetitively arranged on the overall surface of the display area DA. For example, pairs of first sub-emission areas SEA1 and second sub-emission areas SEA2 may be repetitively arranged in the second direction DR2 on the overall surface of the display area DA. In an embodiment, the first sub-emission areas SEA1 and the second sub-emission areas SEA2 may be alternately and repetitively arranged in the second direction DR2. Each of the pairs of first sub-emission areas SEA1 and second sub-emission areas SEA2 may be disposed between the first emission areas EA1 or the second emission areas EA2 of two different unit pixels PX1, PX2, PX3, and PX4. The third emission area EA3 of the first unit pixel PX1 may be disposed between the first and second emission area EA1 and EA2 of the first unit pixel PX1 and the first and second emission areas EA1 and EA2 of the second unit pixel PX2.

For example, the arrangement of the emission areas EA1, EA2, and EA3 is not limited to that depicted in FIG. 5. Similarly to the unit pixels PX1, PX2, PX3, and PX4, the emission areas EA1, EA2, and EA3 may also be arranged in a PENTILE™ type, such as a diamond PENTILE™ type.

The first to third emission areas EA1, EA2, and EA3 may be respectively defined by the pixel openings OPE1, OPE2, and OPE3 formed in the pixel defining layer (refer to PDL of FIG. 6) of the light-emitting-element layer EML. For example, the first emission area EA1 may be defined by the first pixel opening (refer to OPE1 of FIG. 6) of the pixel defining layer. The second emission area EA2 may be defined by the second pixel opening (refer to OPE2 of FIG. 6) of the pixel defining layer. The third emission area EA3 may be defined by the third pixel opening (refer to OPE3 of FIG. 6) of the pixel defining layer.

In an embodiment, the surface areas or sizes of the first to third emission areas EA1, EA2, and EA3 may be different from each other. In an embodiment of FIG. 5, the surface area of the first emission area EA1 may be greater than the surface area of each of the sub-emission areas SEA1 and SEA2 of the second emission area EA2 and the third emission area EA3. The surface area of the second emission area EA2 may be greater than the surface area of each of the sub-emission area SEA1 and SEA2 of the third emission area EA3. The surface areas of the emission areas EA1, EA2, and EA3 may vary according to the sizes of the pixel openings OPE1, OPE2, and OPE3 formed in the pixel defining layer PDL. The surface area of each of the emission areas EA1, EA2, and EA3 may vary, and the intensity of light emitted from the corresponding emission area EA1, EA2, EA3 may vary. The color representation of the screen displayed on the display device 10 or the electronic device 1 may be controlled by adjusting the surface areas of the emission areas EA1, EA2, and EA3. The surface areas of the emission areas EA1, EA2, and EA3 may be related to factors such as light efficiency, and the lifespan of the light emitting element ED, and may be in a trade-off relationship with reflection of external light. The surface areas of the emission areas EA1, EA2, and EA3 may be adjusted based on the factors mentioned above.

In an embodiment, the display device 10 may be designed in such a way that the surface areas of the emission areas EA1, EA2, and EA3 or the surface areas of the pixel openings OPE1, OPE2, and OPE3 of the pixel defining layer PDL transmit reflective light generated from external light to be perceived as a mixture of white light.

The display device 10 may include color filters CF1, CF2, and CF3 disposed on the emission areas EA1, EA2, and EA3. The color filters CF1, CF2, and CF3 may be disposed to overlap the emission areas EA1, EA2, and EA3, or the pixel openings OPE1, OPE2, and OPE3. Each of the color filters CF1, CF2, and CF3 may have a surface area greater than that of the corresponding pixel opening OPE1, OPE2, or OPE3 of the pixel defining layer PDL. Although FIG. 5 illustrates that boundaries of adjacent color filters CF1, CF2, and CF3 are depicted as straight lines, the adjacent color filters CF1, CF2, and CF3 may substantially have overlapping portions which overlap each other with a certain width.

Referring to FIG. 5, the light blocking component BM may form the light openings OPT1, OPT2, and OPT3. The light openings OPT1, OPT2, and OPT3 of the light blocking component BM may be formed to overlap the pixel openings OPE1, OPE2, and OPE3 of the pixel defining layer PDL that correspond to (or overlap) the emission areas EA1, EA2, and EA3, and may form light output areas through which light is emitted from the emission areas EA1, EA2, and EA3. Each of the color filters CF1, CF2, and CF3 may have a surface area greater than that of a corresponding one of the light openings OPT1, OPT2, and OPT3 of the light blocking component BM or a corresponding one of the pixel opening OPE1, OPE2, and OPE3 of the pixel defining layer PDL. Each of the color filters CF1, CF2, and CF3 may cover (e.g., completely cover) the corresponding light output area.

The color filters CF1, CF2, and CF3 may be disposed to respectively correspond to (or to overlap) the emission areas EA1, EA2, and EA3. The color filters CF1, CF3, and CF3 may include a first color filter CF1, a second color filter CF2, and a third color filter CF3 that are disposed respectively corresponding to the respective emission areas EA1, EA2, and EA3. The color filters CF1, CF3, and CF3 may include colorants such as dyes or pigments that absorb light in wavelengths other than a specific wavelength range, and may be disposed to correspond to (or to overlap) the colors of light emitted from the emission areas EA1, EA2, and EA3. For example, the first color filter CF1 may be disposed to overlap the first emission area EA1, and may be a red color filter that selectively transmits only first light of red. The second color filter CF2 may be disposed to overlap the second emission area EA2, and may be a green color filter that selectively transmits only second light of green. The third color filter CF3 may be disposed to overlap the sub-emission areas SEA1 and SEA2 of the third emission area EA3, and may be a blue color filter that selectively transmits only third light of blue.

Similarly to the arrangement of the emission areas EA1, EA2, and EA3, the color filters CF1, CF2, and CF3 may be arranged in the first direction DR1, the second direction DR2, or a diagonal direction therebetween. For example, the first color filter CF1 and the second color filter CF2 may be adjacent to each other in the second direction DR2. In an embodiment, the first color filter CF1 and the second color filter CF2 may be alternately disposed in the overall surface of the display area DA in the second direction DR2. The first color filter CF1 disposed in the third unit pixel PX3 may be disposed between the second color filter CF2 disposed in the first unit pixel PX1 and the second color filter CF2 disposed in the third unit pixel PX3. The third color filter CF3 may be adjacent to the first color filter CF1 and the second color filter CF2 in the first direction DR1. The third emission areas EA3 may be repetitively arranged in the overall surface of the display area DA in the second direction DR2. For example, the third color filter CF3 disposed in the first unit pixel PX1 may be disposed between the second color filter CF2 disposed in the first unit pixel PX1 and the second color filter CF2 disposed in the second unit pixel PX2.

Referring to FIG. 5, the display device 10 may include a color pattern layer CP that protrudes from the first color filter CF1 in the first direction DR1 and is disposed to contact the third color filter CF3 in the second direction DR2. The color pattern layer CP may include the same material as the first color filter CF1, and may be integral with the first color filter CF1. The color pattern layer CP and the first color filter CF1 may include the same material based on the color representation of light reflected by the display device 10, and may be disposed in each of the unit pixels PX1, PX2, PX3, and PX4. The color pattern layer CP may be adjacent to the third color filter CF3 in the second direction DR2. The position at which the color pattern layers CP are disposed may vary for each of the unit pixels PX1, PX2, PX3, and PX4. For example, in the first unit pixel PX1 and the fourth unit pixel PX4, the color pattern layer CP may be disposed on a side, e.g., an upper side, of the third color filter CF3 in the second direction DR2. In the second unit pixel PX2 and the third unit pixel PX3, the color pattern layer CP may be disposed on another side, e.g., a lower side, of the third color filter CF3 in the second direction DR2. The color pattern layer CP may be disposed over two adjacent unit pixels among the unit pixels PX1, PX2, PX3, and PX4 in the second direction DR2. The color pattern layers CP may be disposed in the overall surface of the display area DA at positions spaced apart from each other in the second direction DR2 or a diagonal direction.

In accordance with an embodiment, in the display device 10, the surface areas of the emission areas EA1, EA2, and EA3 may be different from each other, and the surface areas of the color filters CF1, CF2, and CF3 may be different from each other.” The emission areas EA1, EA2, and EA3 may have surface areas that are proportional to each other based on a specific ratio. Likewise, the color filters CF1, CF2, and CF3 may also have surface areas that are proportional to each other based on a specific ratio. For example, the surface area ratio between the emission areas EA1, EA2, and EA3 may differ from the surface area ratio between the color filters CF1, CF2, and CF3. The relatively surface area ratio of the color filters CF1, CF2, and CF3 may influence the color representation of external light reflected by the display device 10. In the display device 10, the color filters CF1, CF2, and CF3 may have surface areas at a specific ratio, and may include a color pattern layer CP including the same material as the red color filter, thereby converting the reflected external light to have comfort color representation for the user's eyes.

For example, the arrangement of the color filters CF1, CF2, and CF3 is not limited to that depicted in FIG. 5. In a manner similar to the arrangement of the emission areas EA1, EA2, and EA3, the color filters CF1, CF2, and CF3 may be arranged in a PENTILE™ type such as a diamond PENTILE™ type. Furthermore, the disposition of the protruded portion of the first color filter CF1 may differ from that depicted in FIG. 5.

In an embodiment, the color filters CF1, CF2, and CF3 may be disposed to partially overlap other adjacent color filters CF1, CF2, and CF3. In an example given in FIG. 5, adjacent color filters CF1, CF2, and CF3 are shown to be disposed in direct contact with each other. However, as will be described below, the adjacent color filters CF1, CF2, and CF3 may include overlapping portions that partially overlap each other along the boundaries therebetween. FIG. 5 illustrates the arrangement of the color filters CF1, CF2, and CF3 in a plan view. For example, among the color filters CF1, CF2, and CF3 overlapping each other, the edge portions of the color filters that are disposed below may be covered with the color filters CF1, CF2, and CF3 that are disposed thereabove. The different color filters CF1, CF2, and CF3 may correspond to (or overlap) areas that do not overlap the emission areas EA1, EA2, and EA3, and may overlap the light blocking component BM in a plan view.

In the display device 10, as the color filters CF1, CF2, and CF3 are disposed to overlap each other, the intensity of reflective light caused by external light may be reduced. Furthermore, the color representation of the reflective light caused by external light may be controlled by adjusting the arrangement, shapes, surface areas, and the like of the color filters CF1, CF2, and CF3.

Hereinafter, the sectional structure taken along line VI-VI′ of FIG. 5 will be described in detail with reference to FIG. 6.

FIG. 6 is a schematic sectional view taken along line VI-VI′ of FIG. 5.

FIG. 6 illustrates a schematic cross-sectional view across the first emission area EA1, the second emission area EA2, and the third emission area EA3.

The display panel 100 of the display device 10 may include a display layer DU, and an external light attenuation layer CFL. The display layer DU may include a substrate SUB, a driving element layer TFTL, a light-emitting-element layer EML, and an encapsulation layer TFEL. In the display panel 100, the external light attenuation layer CFL disposed on the encapsulation layer TFEL may include a light blocking component BM and color filters CF1, CF2, and CF3. The color filters CF1, CF2, and CF3 may be positioned on the light blocking component BM. For example, the light blocking component BM may overlap the overlapping portions of the color filters CF1, CF2, and CF3.

The substrate SUB may be a base substrate or a base component. The substrate SUB may be a flexible substrate which is bendable, foldable, rollable, or the like. For example, the substrate SUB may include polymer resin such as polyimide (PI), but embodiments are not limited thereto. In an embodiment, the substrate SUB may include glass or metal.

The driving element layer TFTL may include a first buffer layer BF1, a bottom metal layer BML, a second buffer layer BF2, a transistor TFT, a gate insulating layer GI, a first interlayer insulating layer ILD1, a capacitor electrode CPE, a second interlayer insulating layer ILD2, a first connection electrode CNE1, a first passivation layer PAS1, a second connection electrode CNE2, and a second passivation layer PAS2.

The first buffer layer BF1 may be disposed on the substrate SUB. The first buffer layer BF1 may include an inorganic layer capable of preventing penetration of air or water. For example, the first buffer layer BF1 may include inorganic layers alternately stacked. In some embodiments, the first buffer layer BF1 may be omitted.

The bottom metal layer BML may be disposed on the first buffer layer BF1. For example, the bottom metal layer BML may have a single layer or multi-layer structure formed of any one of molybdenum (Mo), aluminum (Al), chrome (Cr), gold (Au), titanium (Ti), nickel (Ni), neodymium (Nd), and copper (Cu), or an alloy thereof.

The second buffer layer BF2 may cover the first buffer layer BF1 and the bottom metal layer BML. The second buffer layer BF2 may include an inorganic layer capable of preventing penetration of air or water. For example, the second buffer layer BF2 may include inorganic layers alternately stacked.

The transistor TFT may be disposed on the second buffer layer BF2. The transistor TFT may be a driving transistor or a switching transistor of the pixel circuitry. The transistor TFT may include a semiconductor layer ACT, a source electrode SE, a drain electrode DE, and a gate electrode GE.

The semiconductor layer ACT may be disposed on the second buffer layer BF2. The semiconductor layer ACT may overlap the bottom metal layer BML and the gate electrode GE in the thickness direction, and may be insulated from the gate electrode GE by the gate insulating layer GI. Some portions of the semiconductor layer ACT may form the source electrode SE and the drain electrode DE by making the material of the semiconductor layer ACT conductive. The semiconductor layer ACT may be positioned between the source electrode SE and the drain electrode DE, and may include an undoped channel layer.

The gate electrode GE may be disposed on the gate insulating layer GI. The gate electrode GE may overlap the semiconductor layer ACT with the gate insulating layer GI interposed between the gate electrode GE and the semiconductor layer ACT.

The gate insulating layer GI may be disposed on the semiconductor layer ACT. For example, the gate insulating layer GI may cover the semiconductor layer ACT and the second buffer layer BF2, and may insulate the semiconductor layer ACT from the gate electrode GE. The gate insulating layer GI may include a contact hole through which the first connection electrode CNE1 passes.

The first interlayer insulating layer ILD1 may cover the gate electrode GE and the gate insulating layer GI. The first interlayer insulating layer ILD1 may include a contact hole through which the first connection electrode CNE1 passes. The contact hole of the first interlayer insulating layer ILD1 may be connected to the contact hole of the gate insulating layer GI and a contact hole of the second interlayer insulating layer ILD2.

The capacitor electrode CPE may be disposed on the first interlayer insulating layer ILD1. The capacitor electrode CPE may overlap the gate electrode GE in the thickness direction. The capacitor electrode CPE and the gate electrode GE may form a capacitance. The second interlayer insulating layer ILD2 may cover the capacitor electrode CPE and the first interlayer insulating layer ILD1. The second interlayer insulating layer ILD2 may include a contact hole through which the first connection electrode CNE1 passes. The contact hole of the second interlayer insulating layer ILD2 may be connected to the contact hole of the first interlayer insulating layer ILD1 and the contact hole of the gate insulating layer GI.

The first connection electrode CNE1 may be disposed on the second interlayer insulating layer ILD2. The first connection electrode CNE1 may electrically connect the drain electrode DE of the transistor TFT to the second connection electrode CNE2. The first connection electrode CNE1 may be inserted into (or filled in) the contact holes that are formed in the second interlayer insulating layer ILD2, the first interlayer insulating layer ILD1, and the gate insulating layer GI.

The first passivation layer PAS1 may cover the first connection electrode CNE1 and the second interlayer insulating layer ILD2. The first passivation layer PAS1 may protect the transistor TFT. The first passivation layer PAS1 may include a contact hole through which the second connection electrode CNE2 passes.

The second connection electrode CNE2 may be disposed on the first passivation layer PAS1. The second connection electrode CNE2 may electrically connect the first connection electrode CNE1 to the pixel electrode AE (hereinafter, referred also to as an anode or a first electrode) of the light emitting element ED. The second connection electrode CNE2 may be inserted into (or filled in) a contact hole formed in the first passivation layer PAS1 and be brought into contact with the first connection electrode CNE1.

The second passivation layer PAS2 may cover the second connection electrode CNE2 and the first passivation layer PAS1. The second passivation layer PAS2 may include a contact hole through which the pixel electrode AE of the light emitting element ED passes.

The light-emitting-element layer EML may be disposed on the driving element layer TFTL. The light-emitting-element layer EML may include the light emitting element ED and the pixel defining layer PDL. The light emitting element ED may include a pixel electrode AE, an emission layer EL, and a common electrode CE (hereinafter, referred also to as a second electrode or a cathode). The light emitting element ED may additionally include at least one layer of a hole injection layer, a hole transport layer, an electron injection layer, and an electron transport layer, and may further include functional layers FL positioned on opposite sides of the emission layer EL.

The pixel electrode AE may be disposed on the second passivation layer PAS2. The pixel electrode AE may be disposed to overlap any one of the pixel openings OPE1, OPE2, and OPE3 of the pixel defining layer PDL. The pixel electrode AE may be electrically connected to the drain electrode DE of the transistor TFT through the first and second connection electrodes CNE1 and CNE2.

The emission layer EL may be disposed on the pixel electrode AE. For example, the emission layer EL may be an organic emission layer formed of an organic material, but embodiments are not limited thereto. The functional layers FL may be positioned on the opposite side of the emission layer EL. The functional layer FL positioned between the emission layer EL and the pixel electrode AE may include a hole injection layer and/or a hole transport layer. The functional layer FL positioned between the emission layer EL and the common electrode CE may include an electron transport layer and/or an electron injection layer. In the case where the emission layer EL corresponds to an organic emission layer, In case that the transistor TFT applies a certain voltage to the pixel electrode AE of the light emitting element ED, and the common electrode CE of the light emitting element ED receives a common voltage or a low driving voltage, holes and electrons may move to the emission layer EL respectively through the hole transport layer and the electron transport layer to flow current through the light emitting element ED. As a result, the holes and the electrons may be combined with each other in the emission layer EL, thereby emitting light.

The common electrode CE may be disposed on the emission layer EL. For example, the common electrode CE may be implemented in the form of an electrode which is common to all of the pixels, rather than being divided for pixels. The common electrode CE may be disposed on the emission layer EL in the first to third emission areas EA1, EA2, and EA3, and may be disposed on the pixel defining layer PDL in an area other than the first to third emission areas EA1, EA2, and EA3. The functional layers FL may be positioned between the pixel defining layer PDL and the common electrode CE.

The common electrode CE may receive a common voltage or a low driving voltage. In case that the pixel electrode AE receives a voltage corresponding to a data voltage and the common electrode CE receives a low driving voltage, a potential difference may be formed between the pixel electrode AE and the common electrode CE, and current may flow to enable the emission layer EL to emit light.

The pixel defining layer PDL may include pixel openings OPE1, OPE2, and OPE3, and may be disposed on some portions of the second passivation layer PAS2 and the pixel electrode AE. The pixel defining layer PDL may include a first pixel opening OPE1, a second pixel opening OPE2, and a third pixel opening OPE3. The pixel openings OPE1, OPE2, and OPE3 may expose some portions of the pixel electrode AE. As described above, the pixel openings OPE1, OPE2, and OPE3 of the pixel defining layer PDL may respectively define the first to third emission areas EA1, EA2, and EA3, and the surface areas and sizes thereof may differ from each other. The pixel defining layer PDL may separate and insulate the respective pixel electrodes AE of the light emitting elements ED from each other. The pixel defining layer PDL may be a black pixel defining layer that includes a light-absorbing material to prevent the reflection of external light. For example, the pixel defining layer PDL may include a polyimide (PI) binder, and pigments that include a mixture of red, green, and blue colors. The pixel defining layer PDL may include cardo-based binder resin, and a mixture of lactam black pigment and blue pigment. The pixel defining layer PDL may include carbon block.

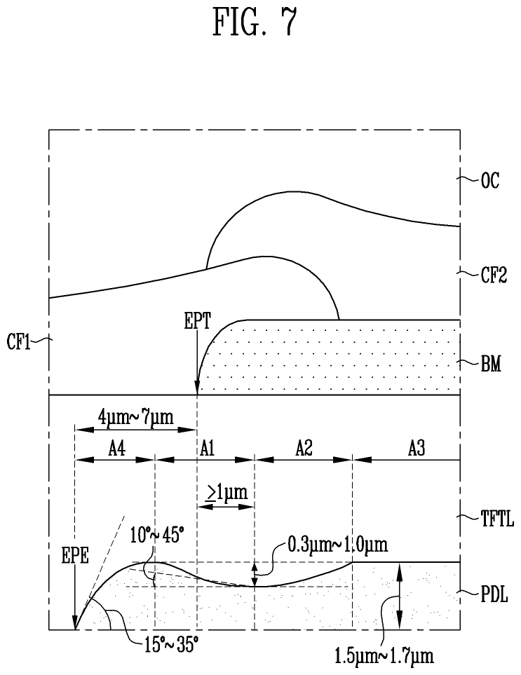

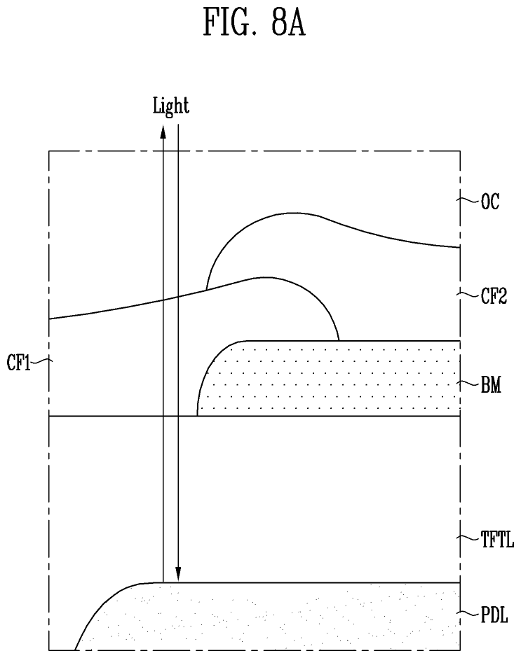

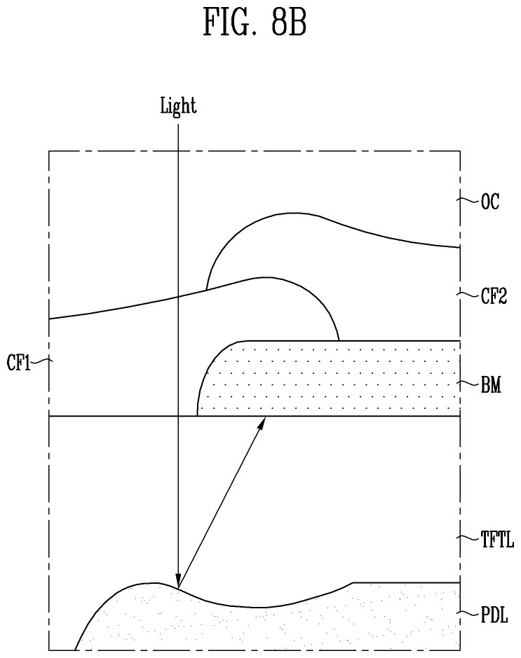

For the convenience of explanation, FIG. 6 depicts that the pixel defining layer PDL has a trapezoidal shape, and a specific shape of the pixel defining layer PDL will be described in detail with reference to FIGS. 7 and 8B.

The encapsulation layer TFEL may be disposed on the common electrode CE to cover the light emitting elements ED. The encapsulation layer TFEL may include at least one inorganic layer to prevent penetration of oxygen or water into the light-emitting-element layer EML. The encapsulation layer TFEL may include at least one organic layer to protect the light-emitting-element layer EML from foreign substances such as dust particles.

The encapsulation layer TFEL in FIG. 6 may include a first encapsulation layer TFE1, a second encapsulation layer TFE2, and a third encapsulation layer TFE3. The first encapsulation layer TFE1 and the third encapsulation layer TFE3 may be an inorganic encapsulation layer, and the second encapsulation layer TFE2 disposed therebetween may be an organic encapsulation layer.

Each of the first encapsulation layer TFE1 and the third encapsulation layer TFE3 may include one or more inorganic insulating materials. The inorganic insulating materials may include aluminum oxide, titanium oxide, tantalum oxide, hafnium oxide, zinc oxide, silicon oxide, silicon nitride, and/or silicon oxynitride.

The second encapsulation layer TFE2 may include a polymer-based material. The polymer-based material may include acrylic resin, epoxy resin, polyimide, polyethylene, and the like. For example, the second encapsulation layer TFE2 may include acrylic-based resin, such as polymethyl methacrylate and polyacrylic acid. The second encapsulation layer TFE2 may be formed by curing a monomer or applying a polymer.

The external light attenuation layer CFL positioned on the encapsulation layer TFEL may include the light blocking component BM and the color filters CF1, CF2, and CF3. The color filters CF1, CF2, and CF3 may be positioned on the light blocking component BM. For example, the light blocking component BM may overlap the overlapping portions of the color filters CF1, CF2, and CF3.

The light blocking component BM may be disposed on the encapsulation layer TFEL. The light blocking component BM may include light openings OPT1, OPT2, and OPT3 disposed to overlap the emission areas EA1, EA2, and EA3. The first light opening OPT1 may be disposed to overlap the first emission area EA1 or the first pixel opening OPE1. The second light opening OPT2 may be disposed to overlap the second emission area EA2 or the second pixel opening OPE2. The third light opening OPT3 may be disposed to overlap the third emission area EA3 or the third pixel opening OPE3. The surface areas or sizes of the light openings OPT1, OPT2, and OPT3 may be respectively greater than the surface areas or sizes of the pixel openings OPE1, OPE2, and OPE3 of the pixel defining layer PDL. As the light openings OPT1, OPT2, and OPT3 of the light blocking component BM are greater than the pixel openings OPE1, OPE2, and OPE3 of the pixel defining layer PDL, light emitted from the emission areas EA1, EA2 and EA3 may be visible to the user not only from the front of the display device 10 but also from the sides of the display device 10.

The light blocking component BM may include a light absorption material. For example, the light blocking component BM may include inorganic black pigments or organic black pigments. The inorganic black pigments may be carbon block. The organic black pigments may include at least one of lactam block, perylene black, and aniline black, but embodiments are not limited thereto. The light blocking component BM may prevent visible rays from penetrating between the first to third emission areas EA1, EA2, and EA3, thereby enhancing the color reproducibility of the display device 10.

The color filters CF1, CF2, and CF3 of the external light attenuation layer CFL may be disposed on the light blocking component BM. The different color filters CF1, CF2, and CF3 may be arranged respectively corresponding to (or overlapping) different emission areas EA1, EA2, and EA3 or the pixel openings OPE1, OPE2, and OPE3 of the pixel defining layer PDL, and the light openings OPT1, OPT2, and OPT3 of the light blocking component BM. For example, the first color filter CF1 may be disposed to correspond to (or to overlap) the first emission area EA1. The second color filter CF2 may be disposed to correspond to (or to overlap) the second emission area EA2. The third color filter CF3 may be disposed to correspond to (or to overlap) the third emission area EA3. The first color filter CF1 may be disposed in the first light opening OPT1 of the light blocking component BM. The second color filter CF2 may be disposed in the second light opening OPT2 of the light blocking component BM. The third color filter CF3 may be disposed in the third light opening OPT3 of the light blocking component BM. The color filters CF1, CF2, and CF3 may be disposed in such a way that respective surface areas thereof in a plan view are greater than that of the light openings OPT1, OPT2, and OPT3 of the light blocking component BM. Some of the color filters CF1, CF2, and CF3 may be disposed (e.g., directly disposed) on the light blocking component BM. The overlapping portions of the color filters CF1, CF2, and CF3 may be positioned on the light blocking component BM.

The external light attenuation layer CFL may further include a planarization layer OC. The planarization layer may be disposed on the color filters CF1, CF2, and CF3 to planarize upper ends of the color filters CF1, CF2, and CF3. The planarization layer OC may be a colorless transparent layer without any color in the visible light band. For example, the planarization layer OC may include colorless transparent organic materials such as acrylic resin.

Hereinafter, characteristics such as the spacing between the pixel defining layer PDL and the light blocking component BM will be described in detail with reference to FIGS. 7 to 8B.

FIG. 7 is a schematic diagram illustrating a pixel defining layer and a light blocking component of the display device in accordance with embodiments. FIG. 8A is a schematic diagram illustrating a comparative example in which external light is incident on the pixel defining layer. FIG. 8B is a schematic diagram illustrating an example where external light is incident on the pixel defining layer of the display device of FIG. 7.

For the convenience of explanation, in FIGS. 7, 8A, and 8B, illustration of layers between the pixel defining layer PDL and the encapsulation layer TFEL is omitted. For the convenience of explanation, FIGS. 7, 8A, and 8B illustrate that the pixel defining layer PDL defining the first pixel opening OPEL includes a first portion A1, and the position where the first portion A1 in accordance with the disclosure is formed is not limited to the pixel defining layer PDL defining the first pixel opening OPE1.

Referring to FIGS. 6, 7, 8A, and 8B, the pixel defining layer PDL may be divided into first to fourth portions A1, A2, A3, and A4. The fourth portion A4 may define the pixel openings OPE1, OPE2, and OPE3. For example, the fourth portion A4 may be adjacent to the pixel openings OPE1, OPE2, and OPE3. The first portion A1 may be adjacent to the fourth portion A4 in a direction away from the pixel openings OPE1, OPE2, and OPE3. The second portion A2 may be adjacent to the first portion A1 in a direction away from the pixel openings OPE1, OPE2, and OPE3. The third portion A3 may be adjacent to the second portion A2 in a direction away from the pixel openings OPE1, OPE2, and OPE3.

The first portion A1 may be inclined. The height of the first portion A1 may decrease in a direction away (or as being farther) from the pixel openings OPE1, OPE2, and OPE3. For example, the first portion A1 may be a tapered portion.

As illustrated in FIG. 8A, in the case where the first portion A1 is planar, external light may be reflected by the pixel defining layer PDL and emitted through the light openings OPT1, OPT2, and OPT3. As illustrated in FIG. 8B, in the case where the first portion A1 forms a tapered portion, external light may be reflected in a direction toward the light blocking component BM. As a result, distortion in color representation by reflective light may be minimized, and the accuracy of prediction for the color represented by the display device may be enhanced.

For example, the inclination of the first portion A1 may range from about 10° to about 45°. In case that the inclination is excessively small or excessively large, external light may be reflected toward the light openings OPT1, OPT2, and OPT3 rather than toward the light blocking component BM.

Although FIG. 7 provides an example where the inclination of the first portion A1 is measured from the tangent on a first portion with the lowest height in the first portion A1, embodiments are not limited thereto. For example, the inclination of the first portion A1 may be an inclination between the first portion with the lowest height and a second portion with the highest height in the first portion A1.

For example, a difference in height between the first portion with the lowest height and the second portion with the highest height in the first portion A1 may range from about 0.3 μm to about 1 μm. In case that the height difference is excessively small or excessively large, external light may be reflected toward the light openings OPT1, OPT2, and OPT3 rather than toward the light blocking component BM.

At least a portion of the first portion A1 may overlap an edge portion EPT of the light blocking component BM. In an embodiment, the first portion with the lowest height in the first portion A1 may overlap the light blocking component BM. For example, the first portion with the lowest height in the first portion A1 may be spaced apart from the edge portion EPT of the light blocking component BM by a horizontal distance of about 1 μm or more.

The edge portion EPT of the light blocking component BM may define the light openings OPT1, OPT2, and OPT3. For example, the edge portion EPT of the light blocking component BM may be adjacent to the light openings OPT1, OPT2, and OPT3.

As the first portion A1 overlaps the edge portion EPT of the light blocking component BM, external light may be incident on an inclined portion (e.g., the first portion A1) of the pixel defining layer PDL rather than being incident on a planar area (e.g., the third portion A3) thereof. Hence, the external light may be reflected toward the light blocking component BM.

In an embodiment, the pixel defining layer PDL may include the second portion A2 that is inclined. The height of the second portion A2 may increase in a direction away (or as being farther) from the pixel openings OPE1, OPE2, and OPE3.

In an embodiment, the pixel defining layer PDL may include the third portion A3 that is formed with a certain height. For example, the height of the third portion A3 may range from about 1.5 μm to about 1.7 μm. For example, the third portion A3 may be a planar area of the pixel defining layer PDL.

In an embodiment, the pixel defining layer PDL may include the fourth portion A4 that is inclined. The fourth portion A4 may have an inclined shape, which is formed by a process of forming the pixel defining layer PDL. For example, the inclination of the fourth portion A4 may range from about 15° to about 35°.

Although FIG. 7 provides an example where the inclination of the fourth portion A4 is measured from the tangent on a portion where the height in the fourth portion A4 is lowest, embodiments are not limited thereto. For example, the inclination of the fourth portion A4 may be an inclination between the portion with the lowest height and a portion with the highest height in the fourth portion A4.

In an embodiment, a horizontal distance between an edge portion EPE of the pixel defining layer PDL and the edge portion EPT of the light blocking component BM may range from about 4 μm to about 7 μm. In the case where the horizontal distance is excessively long, the quantity of external light reflected by the pixel defining layer PDL may be increased.

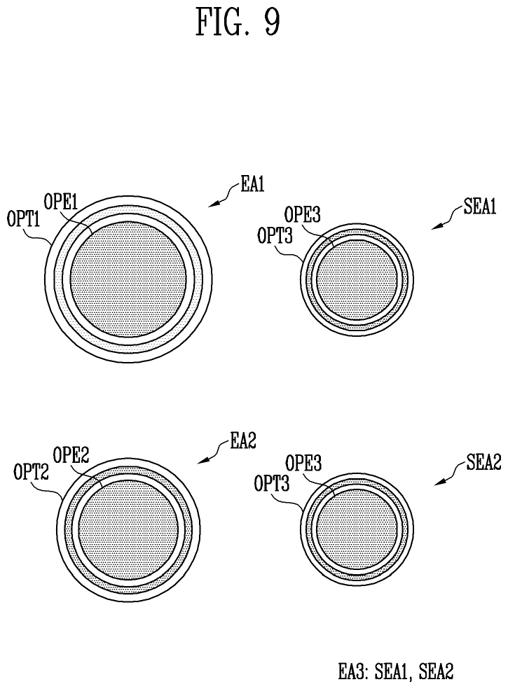

FIG. 9 provides schematic diagrams illustrating the quantity of total reflected light (e.g., specular component included; SCI) from the display device shown in FIG. 7.

FIG. 9 represents darker colors to indicate a higher quantity of reflected light for the convenience of explanation. FIG. 9 represents reflective light, which is reflected by the pixel defining layer PDL and passes through the light openings OPT1, OPT2, and OPT3, as bands between the light openings OPT1, OPT2, and OPT3 and the pixel openings OPE1, OPE2, and OPE3.

Referring to FIGS. 6, 7, and 9, the first portion A1 may be included in a portion of the pixel defining layer PDL that defines the first pixel opening OPE1. Hence, the quantity of external light that is reflected by the pixel defining layer PDL in the first emission area EA1, and the representation of a first color may be controlled or adjusted.

Hence, the quantity of external light that is reflected by the pixel defining layer PDL in the second emission area EA2, and the representation of a second color may be controlled or adjusted.

For example, embodiments are not limited to the first pixel opening OPE1. For example, the first portion A1 may be included in at least one of a portion of the pixel defining layer PDL that defines the second pixel opening OPE2, a portion of the pixel defining layer PDL that defines a first sub-pixel opening (e.g., an opening defining the first sub-emission area SEA1), and a portion of the pixel defining layer PDL that defines a second sub-pixel opening (e.g., an opening defining the second sub-emission area SEA2).

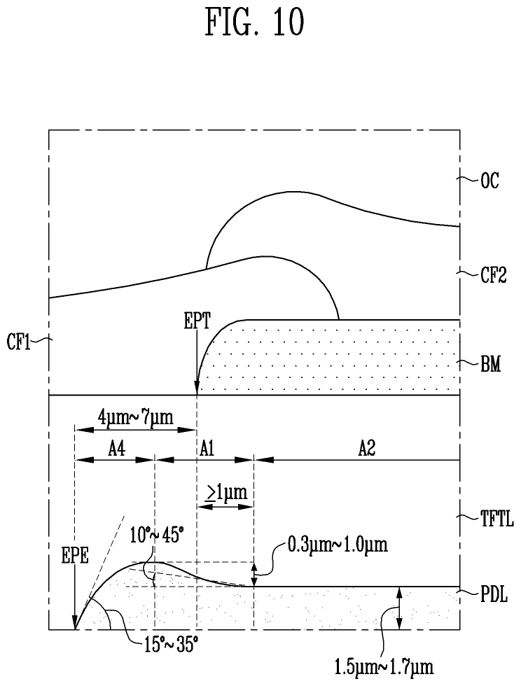

FIG. 10 is a schematic diagram illustrating a pixel defining layer and a light blocking component of the display device in accordance with embodiments.

The configuration of the display device in accordance with the embodiments is substantially the same as that of the display device of FIG. 7, other than the second portion A2; therefore, identical or similar components are denoted by the same reference numerals and symbols, and redundant explanation thereof will be omitted for descriptive convenience.

In FIG. 10, for the convenience of explanation, layers between the pixel defining layer PDL and the encapsulation layer TFEL are omitted. For the convenience of explanation, FIG. 10 illustrates that the pixel defining layer PDL defining the first pixel opening OPE1 includes a first portion A1, and the position where the first portion A1 in accordance with an embodiment is formed is not limited to the pixel defining layer PDL defining the first pixel opening OPE1.

Referring to FIG. 10, the pixel defining layer PDL may be divided into the first, second, and fourth portions A1, A2, and A4. The fourth portion A4 may define the pixel openings OPE1, OPE2, and OPE3. For example, the fourth portion A4 may be adjacent to the pixel openings OPE1, OPE2, and OPE3. The first portion A1 may be adjacent to the fourth portion A4 in a direction away from the pixel openings OPE1, OPE2, and OPE3. The second portion A2 may be adjacent to the first portion A1 in a direction away from the pixel openings OPE1, OPE2, and OPE3.

The pixel defining layer PDL may include the second portion A2 that is formed with a certain height. For example, the height of the second portion A2 may range from about 1.5 μm to about 1.7 μm. For example, the second portion A2 may be a planar area of the pixel defining layer PDL.

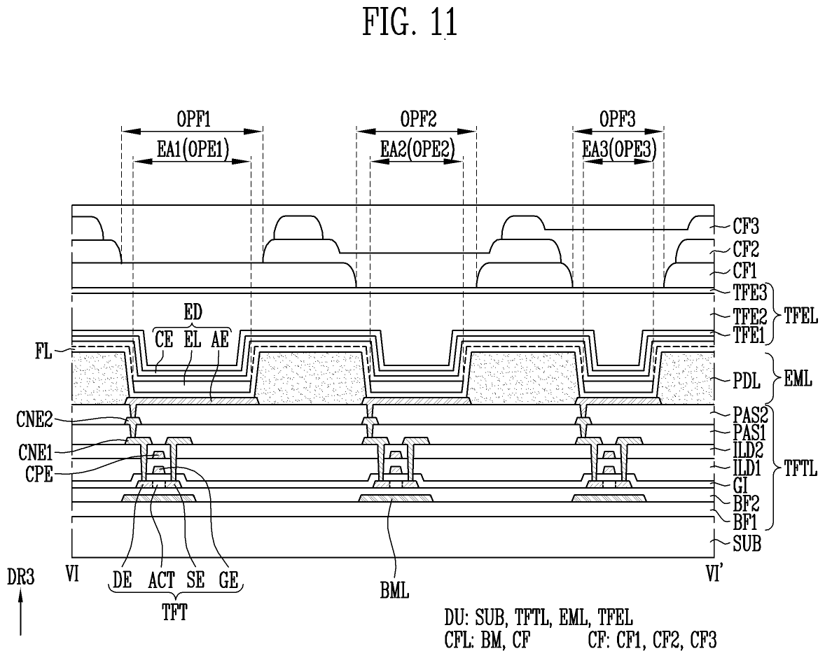

FIG. 11 is a schematic sectional view of the display device taken along line VI-VI′ of FIG. 5, in accordance with embodiments.

The configuration of the display device in accordance with the embodiments is substantially the same as that of the display device of FIG. 6, with the exception for including only the color filters CF1, CF2, and CF3 without a light blocking component; therefore, identical or similar components are denoted by the same reference numerals and symbols, and redundant explanation thereof will be omitted for descriptive convenience.

The first color filter CF1 may be disposed on the encapsulation layer TFEL. The second color filter CF2 may be positioned at least partially on the first color filter CF1. The third color filter CF3 may be positioned at least partially on the second color filter CF2.

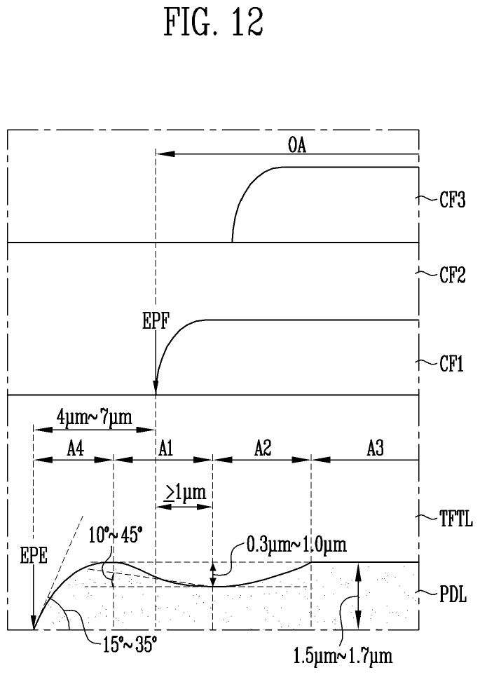

The color filters CF1, CF2, and CF3 may absorb light of different wavelength bands. Therefore, an overlapping area (refer to OA in FIG. 12) where at least two of the color filters CF1, CF2, and CF3 overlap each other may perform a function similar to that of the light blocking component BM in FIG. 6. For example, embodiments are not limited to the wavelength band of light that is absorbed by each of the color filters CF1, CF2, and CF3.

Hereinafter, openings defined by the overlapping area where at least two of the color filters CF1, CF2, and CF3 overlap each other will be referred to as filter openings OPF1, OPF2, and OPF3. For example, the first filter opening OPF1 that overlaps the first pixel opening OPE1 may be defined by the second color filter CF2. For example, the second filter opening OPF2 that overlaps the second pixel opening OPE2 may be defined by the first color filter CF1. For example, the third filter opening OPF3 that overlaps the third pixel opening OPE3 may be defined by the first color filter CF1.

Although in the embodiments, the overlapping area is an example as an area where two of the color filters CF1, CF2, and CF3 overlap each other, embodiments are not limited thereto. For example, the overlapping area may be an area where the three color filters CF1, CF2, and CF3 overlap each other.

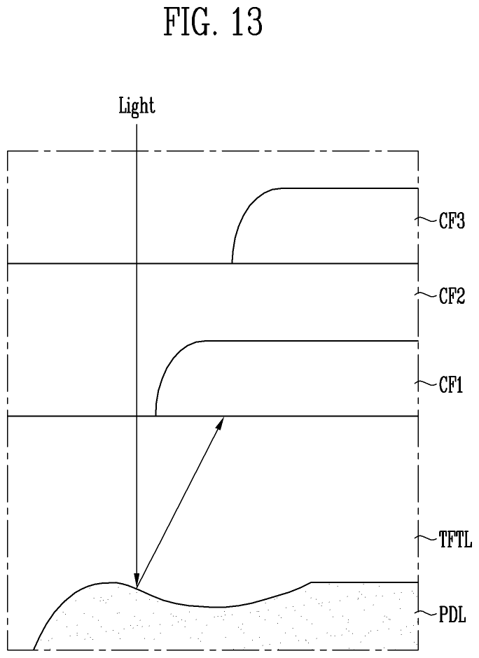

FIG. 12 is a schematic diagram illustrating the pixel defining layer and the color filter of the display device of FIG. 11. FIG. 13 is a schematic diagram illustrating an example where external light is incident on the pixel defining layer of the display device of FIG. 11.

In FIGS. 12 and 13, for the convenience of explanation, layers between the pixel defining layer PDL and the encapsulation layer TFEL are omitted. For the convenience of explanation, FIGS. 12 and 13 illustrates that the pixel defining layer PDL defining the second pixel opening OPE2 includes a first portion A1, and the position where the first portion A1 in accordance with the disclosure is formed is not limited to the pixel defining layer PDL defining the second pixel opening OPE2.

Referring to FIGS. 12 and 13, the pixel defining layer PDL may be divided into the first to fourth portions A1, A2, A3, and A4. The fourth portion A4 may define the pixel openings OPE1, OPE2, and OPE3. For example, the fourth portion A4 may be adjacent to the pixel openings OPE1, OPE2, and OPE3. The first portion A1 may be adjacent to the fourth portion A4 in a direction away from the pixel openings OPE1, OPE2, and OPE3. The second portion A2 may be adjacent to the first portion A1 in a direction away from the pixel openings OPE1, OPE2, and OPE3. The third portion A3 may be adjacent to the second portion A2 in a direction away from the pixel openings OPE1, OPE2, and OPE3.

The first portion A1 may be inclined. The height of the first portion A1 may decrease in a direction away (or as being farther) from the pixel openings OPE1, OPE2, and OPE3. For example, the first portion A1 may be a tapered portion.

As illustrated in FIG. 13, in the case where the first portion A1 forms a tapered portion, external light may be reflected in a direction toward the overlapping area OA. As a result, distortion in color representation by reflective light may be minimized, and the accuracy of prediction for the color represented by the display device may be enhanced.

For example, the inclination of the first portion A1 may range from about 10° to about 45°. In case that the inclination is excessively small or excessively large, external light may be reflected toward the filter openings OPF1, OPF2, and OPF3 rather than toward the overlapping area OA.

Although FIG. 13 provides an example where the inclination of the first portion A1 is measured from the tangent on a first portion with the lowest height in the first portion A1, embodiments are not limited thereto. For example, the inclination of the first portion A1 may be an inclination between the first portion with the lowest height and a second portion with the highest height in the first portion A1.

For example, a difference in height between the first portion with the lowest height and the second portion with the highest height in the first portion A1 may range from about 0.3 μm to about 1 μm. In case that the height difference is excessively small or excessively large, external light may be reflected toward the filter openings OPF1, OPF2, and OPF3 rather than toward the overlapping area OA.

At least a portion of the first portion A1 may overlap an edge portion EPF of the overlapping area OA. In an embodiment, the first portion with the lowest height in the first portion A1 may overlap the overlapping area OA. For example, the first portion with the lowest height in the first portion A1 may be spaced apart from the edge portion of the overlapping area OA (in the case of FIG. 12, an edge portion EPF of the first color filter CF1) by a horizontal distance of about 1 μm or more.

The edge portion of the overlapping area OA may define the filter openings OPF1, OPF2, and OPF3. For example, the edge portion of the overlapping area OA may be adjacent to the filter openings OPF1, OPF2, and OPF3.

As the first portion A1 overlaps the edge portion of the overlapping area OA, external light may be incident on an inclined portion (e.g., the first portion A1) of the pixel defining layer PDL rather than being incident on a planar area (e.g., the third portion A3) thereof. Hence, the external light may be reflected toward the overlapping area OA.

In an embodiment, the pixel defining layer PDL may include the second portion A2 that is inclined. The height of the second portion A2 may increase in a direction away (or as being farther) from the pixel openings OPE1, OPE2, and OPE3.

In an embodiment, the pixel defining layer PDL may include the third portion A3 that is formed with a certain height. For example, the height of the third portion A3 may range from about 1.5 μm to about 1.7 μm. For example, the third portion A3 may be a planar area of the pixel defining layer PDL.

In an embodiment, the pixel defining layer PDL may include the fourth portion A4 that is inclined. The fourth portion A4 may have an inclined shape resulting from a process of forming the pixel defining layer PDL. For example, the inclination of the fourth portion A4 may range from about 15° to about 35°.

Although FIG. 12 provides an example where the inclination of the fourth portion A4 is measured from the tangent on a portion where the height in the fourth portion A4 is lowest, embodiments are not limited thereto. For example, the inclination of the fourth portion A4 may be an inclination between the portion with the lowest height and a portion with the highest height in the fourth portion A4.

In an embodiment, a horizontal distance between an edge portion EPE of the pixel defining layer PDL and the edge portion of the overlapping area OA may range from about 4 μm to about 7 μm. In the case where the horizontal distance is excessively long, the quantity of external light reflected by the pixel defining layer PDL may be increased.

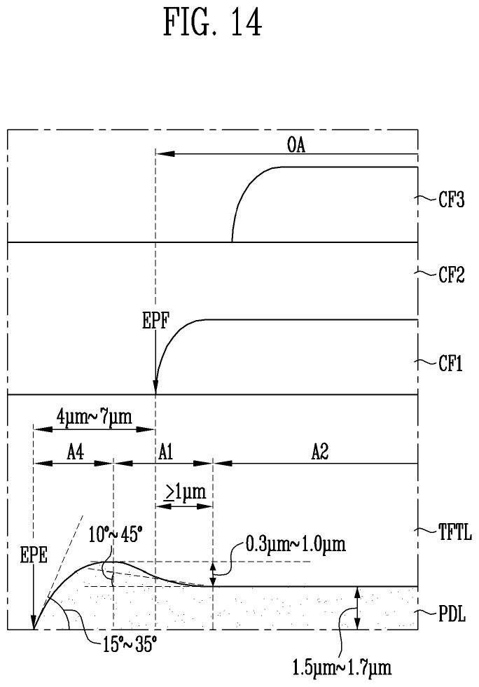

FIG. 14 is a schematic diagram illustrating the pixel defining layer and the color filter of the display device in accordance with embodiments.

The configuration of the display device in accordance with the embodiments is substantially the same as that of the display device of FIG. 12, other than the second portion A2; therefore, identical or similar components are denoted by the same reference numerals and symbols, and redundant explanation thereof will be omitted for descriptive convenience.

In FIG. 14, for the convenience of explanation, layers between the pixel defining layer PDL and the encapsulation layer TFEL are omitted. For the convenience of explanation, FIG. 14 illustrates that the pixel defining layer PDL defining the second pixel opening OPE2 includes a first portion A1, and the position where the first portion A1 in accordance with the disclosure is formed is not limited to the pixel defining layer PDL defining the second pixel opening OPE2.

Referring to FIG. 14, the pixel defining layer PDL may be divided into the first, second, and fourth portions A1, A2, and A4. The fourth portion A4 may define the pixel openings OPE1, OPE2, and OPE3. For example, the fourth portion A4 may be adjacent to the pixel openings OPE1, OPE2, and OPE3. The first portion A1 may be adjacent to the fourth portion A4 in a direction away from the pixel openings OPE1, OPE2, and OPE3. The second portion A2 may be adjacent to the first portion A1 in a direction away from the pixel openings OPE1, OPE2, and OPE3.

The pixel defining layer PDL may include the second portion A2 that is formed with a certain height. For example, the height of the second portion A2 may range from about 1.5 μm to about 1.7 μm. For example, the second portion A2 may be a planar area of the pixel defining layer PDL.

The disclosure may be applied to a display device and an electronic device including the display device. For example, the disclosure may be applied to digital TVs, 3D TVs, cellular phones, smartphones, tablet computers, VR devices, PCs, home appliances, laptop computers, PDAs, portable media players (PMPs), digital cameras, music players, portable game consoles, navigation devices, and so on.

A display device in accordance with embodiments may include a pixel defining layer having an inclined portion to enable external light to be reflected toward a light blocking component (or an overlapping area). As a result, distortion in color representation by reflective light may be minimized, and the accuracy of prediction for the color represented by the display device may be enhanced.

In concluding the detailed description, those skilled in the art will appreciate that many variations and modifications may be made to the embodiments without substantially departing from the principles and spirit and scope of the disclosure. Therefore, the disclosed embodiments are used in a generic and descriptive sense only and not for purposes of limitation.

What is claimed is:

1. A display device comprising:
a substrate;
a first electrode disposed on the substrate;
a pixel defining layer including a pixel opening through which the first electrode is exposed;
a second electrode disposed on the pixel defining layer and the first electrode;
an encapsulation layer covering the second electrode;
a color filter disposed on the encapsulation layer; and
a light blocking component including a light opening overlapping the color filter, wherein
the pixel defining layer includes a first portion,
at least a portion of the first portion overlaps an edge portion of the light blocking component, and
the first portion is inclined.

2. The display device of claim 1, wherein a height of the first portion decreases as being farther from the pixel opening.

3. The display device of claim 1, wherein an inclination of the first portion is in a range of about 10° to about 45°.

4. The display device of claim 1, wherein a first portion with a lowest height in the first portion overlaps the light blocking component.

5. The display device of claim 1, wherein a first portion with a lowest height in the first portion is spaced apart from the edge portion of the light blocking component by a horizontal distance of about 1 μm or more.

6. The display device of claim 1, wherein a difference in height between a first portion with a lowest height and a second portion with a highest height in the first portion is in a range of about 0.3 μm to about 1 μm.

7. The display device of claim 1, wherein
the pixel defining layer further includes a second portion adjacent to the first portion as being farther from the pixel opening, and
the second portion is inclined.

8. The display device of claim 7, wherein a height in the second portion increases as being farther from the pixel opening.

9. The display device of claim 7, wherein
the pixel defining layer further includes a third portion adjacent to the second portion as being farther from the pixel opening, and
the third portion has a certain height.

10. The display device of claim 9, wherein the height of the third portion is in a range of about 1.5 μm to about 1.7 μm.

11. The display device of claim 1, wherein
the pixel defining layer further includes a second portion adjacent to the first portion as being farther from the pixel opening, and
the second portion has a certain height.

12. The display device of claim 1, wherein
the pixel defining layer further includes a fourth portion adjacent to the first portion in a direction toward the pixel opening, and
the fourth portion is inclined.

13. The display device of claim 12, wherein an inclination of the fourth portion is in a range of about 15° to about 35°.

14. The display device of claim 1, wherein the pixel opening has a surface area less than a surface area of the light opening.

15. The display device of claim 1, wherein
the pixel opening includes:
a first pixel opening defining a first emission area formed to display a first color,
a second pixel opening defining a second emission area formed to display a second color, and
a third pixel opening defining a third emission area formed to display a third color, and
the first portion is included in a portion of the pixel defining layer that defines the first pixel opening.

16. The display device of claim 1, wherein
the pixel opening includes:
a first pixel opening defining a first emission area formed to display a first color,
a second pixel opening defining a second emission area formed to display a second color,
a first sub-pixel opening defining a first sub-emission area formed to display a third color, and
a second sub-pixel opening defining a second sub-emission area formed to display the third color, and
the first portion is included in a portion of the pixel defining layer that defines the first sub-pixel opening.

17. A display device comprising:
a substrate;
a first electrode disposed on the substrate;
a pixel defining layer including a pixel opening through which the first electrode is exposed;
a second electrode disposed on the pixel defining layer and the first electrode;
an encapsulation layer covering the second electrode;
a first color filter disposed on the encapsulation layer; and
a second color filter disposed at least partially over the first color filter, wherein the pixel defining layer includes a first portion,
at least a portion of the first portion overlaps an edge portion of an overlapping area where the first color filter and the second color filter overlap each other, and
the first portion is inclined.

18. The display device of claim 17, wherein a height of the first portion decreases as being farther from the pixel opening.

19. The display device of claim 17, wherein a first portion with a lowest height in the first portion overlaps the overlapping area.

20. The display device of claim 17, wherein a first portion with a lowest height in the first portion is spaced apart from the edge portion of the overlapping area by a horizontal distance of about 1 μm or more.
